(19) United States
(12) Patent Application Publication
(10) Pub. No.: US 2014/0158532 A1
(43) Pub. Date: Jun. 12, 2014

(54) HIGH-PURITY COPPER-MANGANESE-ALLOY SPUTTERING TARGET

(71) Applicants: Kenichi Nagata, Ibaraki (JP); Tomio Otsuki, Ibraki (JP); Takeo Okabe, Ibaraki (JP); Nobuhito Makino, Ibaraki (JP); Atsushi Fukushima, Ibaraki (JP)

(72) Inventors: Kenichi Nagata, Ibaraki (JP); Tomio Otsuki, Ibraki (JP); Takeo Okabe, Ibaraki (JP); Nobuhito Makino, Ibaraki (JP); Atsushi Fukushima, Ibaraki (JP)

(73) Assignee: JX NIPPON MINING & METALS CORPORATION, Tokyo (JP)

(21) Appl. No.: 14/235,865

(22) PCT Filed: Sep. 5, 2012
(86) PCT No.: PCT/JP2012/072541

§ 371 Date: Jan. 29, 2014

(30) Foreign Application Priority Data
Sep. 14, 2011 (JP) 2011-200228

(51) Int. Cl. C23C 14/14

(52) U.S. Cl. CPC C23C 14/14
USPC 204/298.13

(57) ABSTRACT

Provided is a high-purity copper-manganese-alloy sputtering target comprising 0.05 to 20 wt. % of Mn, 2 wt ppm or less of C, and the remainder being Cu and inevitable impurities, wherein in formation of a film on a wafer by sputtering the target, the number of particles composed of C, at least one element selected from Mn, Si, and Mg, or a compound composed of C and at least one element selected from Mn, Si, and Mg and having a diameter of 0.20 μm or more is 30 or less on average. Particle generation during sputtering can be effectively suppressed by thus adding an appropriate amount of Mn element to copper and controlling the amount of carbon. In particular, a high-purity copper-manganese-alloy sputtering target that is useful for forming semiconductor copper alloy line having a self-diffusion suppression function is provided.

### TECHNICAL FIELD

The present invention relates to a high-purity copper-manganese-alloy that has a self-diffusion suppression function useful and suitable for forming a semiconductor copper alloy line and can effectively prevent contamination of the periphery of the line due to diffusion of active copper. The invention particularly relates to a high-purity copper-manganese-alloy sputtering target with less particle generation.

### BACKGROUND ART

Conventionally, Al alloys, of which specific resistance is about 3.0 μΩ cm, were used as a metal line material of semiconductor devices. However, a copper line having a lower resistance, of which specific resistance is about 2.0 ˜Ω·cm, has been put into practical use with miniaturization of metal lines. A copper line is generally formed by forming a diffusion barrier layer of, for example, Ta or TaN in a line or a via hole and then forming a film of copper by sputtering. Copper having a high purity of 5 to 6 N is usually produced from electrolytic copper having a purity of about 4 N (excluding gas components) as a crude metal by a wet or dry purification process, and the purified copper is used as a sputtering target.

As described above, copper is very effective for semiconductor metal lines, however, copper itself is a very active metal and easily diffuses, and thus causes a problem of contaminating a Si substrate or its periphery through the semiconductor Si substrate or the insulating film thereon. In particular, with progress in miniaturization of lines, the problem cannot be sufficiently prevented by the conventional diffusion barrier layer of Ta or TaN only, and copper line materials themselves also need to be improved. Accordingly, as a copper line material, a Cu—Mn alloy, which is a copper alloy prepared by adding manganese (Mn) to copper (Cu), having a self-diffusion suppression function by forming a barrier layer by itself through a reaction of Mn in the Cu—Mn alloy with oxygen in an insulating film, has been proposed.

The semiconductor copper alloy line is formed using a copper-manganese alloy sputtering target. In such a semiconductor copper alloy line, fine particles cause a problem of affecting a circuit with progresses of miniaturization, density growth, and integration of semiconductor devices and with progresses of miniaturization and increase in number of metal line layers, though conventionally the particles have not caused any problem. Hence, it is an urgent issue to more strictly prevent the generation of particles during sputtering and to reduce particles on a semiconductor wafer.

The followings are examples of the Cu—Mn alloy sputtering target: Patent Literature 1 describes a sputtering target composed of 0.1 to 20.0 at. % of Mn, 0.05 at. % or less of inevitable impurity elements having diffusion coefficients lower than the self-diffusion coefficient of Cu, and the remainder being Cu;

Patent Literature 2 describes a sputtering target composed of 0.1 to 1.0 at. % of B as an additive element, 0.1 to 2.0 at. % of Mn and/or Ni, and the remainder being Cu and inevitable impurities;

Patent Literature 3 describes a sputtering target composed of 0.1 to 1.0 at. % of B as an additive element, 0.1 to 2.0 at. % of an element (including Mn) that forms a compound with B, and the remainder being Cu and inevitable impurities;

Patent Literature 4 describes a sputtering target composed of at least one component selected from the group consisting of V, Nb, Fe, Co, Ni, Zn, and Mg and at least one component selected from the group consisting of Sc, Al, Y, and Cr in a total amount of 0.005 to 0.5% by mass, 0.1 to 5 ppm of oxygen, and the remainder being Cu and inevitable impurities;

Patent Literature 5 describes a sputtering target composed of oxygen in an amount of higher than 6% by mole and 20% by mole or less, at least one selected from Mo, Mn, Ca, Zn, Ni, Ti, Al, Mg, and Fe in a total amount of 0.2 to 5% by mole, and the remainder being Cu and inevitable impurities; and

Patent Literature 6 describes a sintered sputtering target material composed of a metal powder of Mn, B, Bi, or Ge and an alloy powder or sintered metal containing X (including Cu) and Y, in which the amount of crystal grains having an average particle diameter of 0.1 to 300 μm is 50% or more, and the amount of gas included is 600 ppm or less.

However, there is a problem that these sputtering targets are not necessarily sufficient for preventing particle generation during sputtering.

Furthermore, the present applicant has proposed a semiconductor device metal line material, which is a sputtering target for forming a semiconductor copper alloy line and composed of Mn in an amount of 0.05 to 5 wt. %, at least one element selected from Sb, Zr, Ti, Cr, Ag, Au, Cd, In, and As in a total amount of 10 wt ppm or less, and the remainder being Cu (see Patent Literature 7).

This is effective for enhancing the self-diffusion suppression function, but the purpose thereof is not suppression of particle generation.

The present applicant has previously disclosed a semiconductor copper alloy line material composed of a Cu—Mn alloy (see Patent Literature 8), in particular, has proposed a sputtering target composed of 0.05 to 20 wt. % of Mn, a total amount of 500 wt ppm or less of Be, B, Mg, Al, Si, Ca, Ba, La, and Ce, and the remainder being Cu and inevitable impurities.

This is also effective for enhancing the self-diffusion suppression function, but the purpose thereof is not suppression of particle generation.

Regarding the suppression of particle generation, a sputtering target composed of 0.6 to 30% by mass of Mn, 40 ppm or less of metal impurities, 10 ppm or less of oxygen, 5 ppm or less of nitrogen, 5 ppm or less of hydrogen, 10 ppm or less of carbon, and the remainder being Cu has been described (see Patent Literature 9).

However, this describes that particle generation can be suppressed by reducing the total amount of impurities contained in the target, and it is unclear which impurity element specifically contributes to generation of particles.

### CITATION LIST

### Patent Literature

Patent Literature 1: Japanese Patent No. 4065959
Patent Literature 2: Japanese Patent Laid-Open No. 2009-97085
Patent Literature 3: Japanese Patent Laid-Open No. 2010-248619
Patent Literature 4: Japanese Patent Laid-Open No. 2002-294437
Patent Literature 5: Japanese Patent Laid-Open No. 2008-311283
Patent Literature 6: Japanese Patent Laid-Open No. 2009-741127
Patent Literature 7: Japanese Patent Laid-Open No. 2006-73863
Patent Literature 8: International Publication No. WO2008/041535
Patent Literature 9: Japanese Patent Laid-Open No. 2007-51351

### SUMMARY OF THE INVENTION

### Technical Problem

It is an object of the present invention to suppress particle generation during sputtering by adding an appropriate amount of Mn element to copper and controlling the amount of carbon. This enables successful formation of a metal line (via) of fine semiconductor devices and can improve the yield and the reliability of semiconductor products, which have been progressing in miniaturization and integration. In addition, the invention provides a high-purity copper-manganese-alloy sputtering target useful for forming a semiconductor copper alloy line having a self-diffusion suppression function, capable of effectively preventing the periphery of the metal line from being contaminated by diffusion of active Cu, and having excellent, for example, electron migration (EM) resistance and corrosion resistance.

### Solution to Problem

In order to solve the above-mentioned problems, the present inventors have diligently studied and, as a result, have found that the main component of the particles is carbon and that there is a correlation between the amount of carbon contained in a target and the number of particles. The inventors further discovered that by adding an appropriate amount of Mn element to copper and controlling the carbon amount, a high-purity copper alloy sputtering target which enables to considerably reduce the amount of particles generated during sputtering and is useful for forming a semiconductor copper alloy line can be obtained.

Based on these findings, the present invention provides:

1) A high-purity copper-manganese-alloy sputtering target comprising 0.05 to 20 wt. % of Mn, 2 wt ppm or less of C, and the remainder being Cu and inevitable impurities, wherein in formation of a film on a wafer by sputtering the target, the number of particles composed of C, at least one element selected from Mn, Si, and Mg, or a compound composed of C and at least one element selected from Mn, Si, and Mg and having a diameter of 0.08 μm or more is 50 or less on average;

2) The high-purity copper-manganese-alloy sputtering target according to 1) above, wherein the number of particles having a diameter of 0.08 μm or more is 20 or less on average;

3) A high-purity copper-manganese-alloy sputtering target comprising 0.05 to 20 wt. % of Mn, 2 wt ppm or less of C, and the remainder being Cu and inevitable impurities, wherein in formation of a film on a wafer by sputtering the target, the number of particles composed of C, at least one element selected from Mn, Si, and Mg, or a compound composed of C and at least one element selected from Mn, Si, and Mg and having a diameter of 0.20 μm or more is 30 or less on average; and

4) The high-purity copper-manganese-alloy sputtering target according to 3) above, wherein the number of particles having a diameter of 0.20 μm or more is 10 or less on average.

### Effects of Invention

The high-purity copper-manganese-alloy sputtering target of the present invention can successfully form a metal line (via) of fine semiconductor devices by suppressing particle generation during sputtering through control of the amount of carbon. A copper alloy line film formed using the high-purity copper-manganese-alloy sputtering target of the present invention has excellent effects of effectively preventing contamination of the periphery of the metal line due to diffusion of active Cu and improving, for example, electron migration (EM) resistance and corrosion resistance.

### DETAILED DESCRIPTION OF THE INVENTION

As described above, the high-purity copper-manganese-alloy sputtering target of the present invention is composed of 0.05 to 20 wt. % of Mn, 2 wt ppm or less of C, and the remainder being Cu and inevitable impurities. In formation of a film by sputtering the target, the number of particles composed of C or C and at least one element selected from Mn, Si, and Mg and having a diameter of 0.08 μm or more on a wafer is 50 or less on average.

In the present invention, the amount of Mn contained in a Cu alloy is desirably 0.05 wt. % or more and 20 wt. % or less. An amount of Mn less than 0.05 wt. % reduces the self-diffusion suppression function whereas an amount of Mn exceeding 20 wt. % increases the resistance and thereby disadvantageously reduces the performance in terms of semiconductor copper alloy lines. More preferably, a copper alloy contains Mn at 0.5 to 10 wt. %.

Furthermore, since carbon contamination occurs from melting materials and apparatus members during the melting step, the Mn content may directly affect the amount of carbon that causes particle generation. Accordingly, the Mn content is required to be exactly controlled within the above-mentioned range.

In addition, in the present invention, the carbon (C) content in the high-purity copper-manganese-alloy sputtering target is preferably 2 wt ppm or less, more preferably 1 wt ppm or less. The impurities contained in the target cause particle generation, and it is therefore desirable to reduce the amount as much as possible. In particular, since carbon (C) directly affects particles being generated during sputtering of a high-purity copper-manganese-alloy target, it is necessary to sufficiently control it.

In addition, in the present invention, the number of particles having a diameter of 0.20 μm or more on a 300-mm wafer is 30 or less on average and preferably 10 or less on average. In addition, regarding particles having a diameter of 0.08 μm or more, the number of the particles on a 300-mm wafer is 50 or less on average and preferably 20 or less on average. The suppression of particle generation allows successful formation of a metal line (via) of fine semiconductor devices and can improve the yield and the reliability of semiconductor products which have been progressing in miniaturization and integration.

In addition, in the present invention, the component of individual particles generated in sputtering using the high-purity copper-manganese-alloy sputtering target is carbon (C), at least one element selected from Mn, Si, and Mg, or a compound composed of carbon (C) and at least one selected from Mn, Si, and Mg. In the present invention, the particles might only be one type of these particles of different components or a mixture of two or more types of these particles of different components. Note that the Mn is derived from addition and that the Si and the Mg are derived from the crucible used in production of the target.

In addition, in the production of the high-purity copper-manganese-alloy sputtering target in the present invention, high-purity copper having a purity of 6 N or more and manganese, an additive element, having a purity of 5 N or more are molten in a carbon crucible. Alternatively, high-purity copper having a purity of 6 N or more is molten in a carbon crucible in advance, and manganese having a purity of 4 N is then added thereto so as to give a desired component composition.

Herein, the important point is melting conditions. The melting temperature is preferably 1000° C. to 1400° C. A temperature lower than 1000° C. does not allow sufficient melting reaction, whereas a temperature higher than 1400° C. disadvantageously causes contamination of carbon from the carbon crucible. The melting period of time is preferably 10 to 30 minutes. A melting time shorter than 10 minutes does not allow sufficient melting reaction, whereas a melting time longer than 30 minutes disadvantageously causes contamination of carbon from the carbon crucible.

A high-purity copper-manganese-alloy ingot having a predetermined component composition can be obtained by casting the resulting alloy. Subsequently, the copper-manganese-alloy ingot is hot-forged at about 500° C. to 900° C. and cold-rolled or, as needed, hot-rolled at 500° C. to 900° C. to give a rolled sheet. The hot-rolling is performed when rolling is difficult because of occurrence of cracking during cold-rolling due to hardening with an increase in amount of manganese. The critical mass of Mn is about 5%, but this critical mass for rolling depends on rolling amount and can be arbitrarily selected and be varied according to conditions. Accordingly, the critical mass is not particularly limited.

The rolled sheet is further heat-treated at 300° C. to 600° C. (in hot-rolling, at 500° C. to 800° C.) and is then bonded to a backing plate, followed by finishing processing. Thus, a sputtering target assembly is produced from the high-purity copper-manganese-alloy.

It is readily understood by those skilled in the art that these production steps can be appropriately selected depending on the component composition, thickness, and size of the target and, in particular, are not limited to the above-mentioned numerical values.

### EXAMPLES

The present invention will now be described by examples. The following examples are intended to facilitate understanding and do not limit the present invention. That is, modifications and other examples based on the technical idea of the present invention are included in the present invention.

### Example 1

High-purity copper (Cu) having a purity of 6 N was melted in a carbon crucible under a high vacuum atmosphere. High-purity manganese (Mn) having a purity of 5 N was charged into the molten copper. The amount of Mn was adjusted to 1 wt. %.

The molten copper-manganese alloy prepared by charging of the Mn and melting at 1200° C. for 20 minutes was cast in a water-cooled copper mold under a high vacuum atmosphere to give an ingot. Subsequently, the surface layer of the produced ingot was removed to give a size of φ160×60 t, followed by hot-forging at 800° C. into φ200. Subsequently, cold-rolling and hot-rolling at 800° C. were performed to give a size of φ380×10 t.

Subsequently, after heat treatment at 600° C. for 1 hour, the entire target was quenched to give a target material. The target material was machined into a target having a diameter of 430 mm and a thickness of 7 mm, which was further diffusion bonded to a Cu alloy backing plate into a sputtering target assembly.

### Example 2

High-purity copper (Cu) having a purity of 6 N was melted in a carbon crucible under a high vacuum atmosphere. High-purity manganese (Mn) having a purity of 5 N was charged into the molten copper. The amount of Mn was adjusted to 10 wt. %.

The molten copper-manganese alloy prepared by charging of the Mn and melting at 1200° C. for 20 minutes was cast in a water-cooled copper mold under a high vacuum atmosphere to give an ingot. Subsequently, the surface layer of the produced ingot was removed to give a size of φ160×60 t, followed by hot-forging at 900° C. into φ200. Subsequently, cold-rolling and hot-rolling at 900° C. were performed to give a size of φ380×10 t.

Subsequently, after heat treatment at 600° C. for 1 hour, the entire target was quenched to give a target material. The target material was machined into a target having a diameter of 430 mm and a thickness of 7 mm, which was further diffusion bonded to a Cu alloy backing plate into a sputtering target assembly.

### Example 3

High-purity copper (Cu) having a purity of 6 N was melted in a carbon crucible under a high vacuum atmosphere. High-purity manganese (Mn) having a purity of 5 N was charged into the molten copper. The amount of Mn was adjusted to 1 wt. %.

The molten copper-manganese alloy prepared by charging of the Mn and melting at 1200° C. for 20 minutes was cast in a water-cooled copper mold under a high vacuum atmosphere to give an ingot. Subsequently, the surface layer of the produced ingot was removed to give a size of φ160×190 t, followed by hot-forging at 900° C. into φ200. Subsequently, cold-rolling and hot-rolling at 900° C. were performed to give a size of φ700×10 t.

Subsequently, after heat treatment at 600° C. for 1 hour, the entire target was quenched to give a target material. The target material was machined into a target having a diameter of 650 mm and a thickness of 7 mm. The target was further machined so as to have a diameter of 430 mm and a thickness of 7 mm, which was diffusion bonded to a Cu alloy backing plate into a sputtering target assembly.

### Example 4

High-purity copper (Cu) having a purity of 6 N was melted in a carbon crucible under a high vacuum atmosphere. High-purity manganese (Mn) having a purity of 5 N was charged into the molten copper. The amount of Mn was adjusted to 10 wt. %.

The molten copper-manganese alloy prepared by charging of the Mn and melting at 1200° C. for 20 minutes was cast in a water-cooled copper mold under a high vacuum atmosphere to give an ingot. Subsequently, the surface layer of the produced ingot was removed to give a size of φ160×190 t, followed by hot-forging at 900° C. into φ200. Subsequently, cold-rolling and hot-rolling at 900° C. were performed to give a size of φ700×10 t.

Subsequently, after heat treatment at 600° C. for 1 hour, the entire target was quenched to give a target material. The target material was machined into a target having a diameter of 650 mm and a thickness of 7 mm. The target was further machined so as to have a diameter of 430 mm and a thickness of 7 mm, which was diffusion bonded to a Cu alloy backing plate into a sputtering target assembly.

### Comparative Example 1

High-purity copper (Cu) having a purity of 6 N was melted in a carbon crucible under a high vacuum atmosphere. High-purity manganese (Mn) having a purity of 5 N was charged into the molten copper. The amount of Mn was adjusted to 1 wt. %.

The molten copper-manganese alloy prepared by charging of the Mn and melting at 1500° C. for 40 minutes was cast in a water-cooled copper mold under a high vacuum atmosphere to give an ingot. Subsequently, the surface layer of the produced ingot was removed to give a size of φ160×60t, followed by hot-forging at 800° C. into φ200. Subsequently, cold-rolling and hot-rolling at 800° C. were performed to give a size of φ380×10 t.

Subsequently, after heat treatment at 600° C. for 1 hour, the entire target was quenched to give a target material. The target material was machined into a target having a diameter of 430 mm and a thickness of 7 mm, which was further diffusion bonded to a Cu alloy backing plate into a sputtering target assembly.

### Comparative Example 2

High-purity copper (Cu) having a purity of 6 N was melted in a carbon crucible under a high vacuum atmosphere. High-purity manganese (Mn) having a purity of 5 N was charged into the molten copper. The amount of Mn was adjusted to 10 wt. %.

The molten copper-manganese alloy prepared by charging of the Mn and melting at 1500° C. for 40 minutes was cast in a water-cooled copper mold under a high vacuum atmosphere to give an ingot. Subsequently, the surface layer of the produced ingot was removed to give a size of φ160×60 t, followed by hot-forging at 900° C. into φ200. Subsequently, cold-rolling and hot-rolling at 900° C. were performed to give a size of φ380×10 t.

Subsequently, after heat treatment at 600° C. for 1 hour, the entire target was quenched to give a target material. The target material was machined into a target having a diameter of 430 mm and a thickness of 7 mm, which was further diffusion bonded to a Cu alloy backing plate into a sputtering target assembly.

### Comparative Example 3

High-purity copper (Cu) having a purity of 6 N was melted in a carbon crucible under a high vacuum atmosphere. High-purity manganese (Mn) having a purity of 5 N was charged into the molten copper. The amount of Mn was adjusted to 10 wt. %.

The molten copper-manganese alloy prepared by charging of the Mn and melting at 1500° C. for 40 minutes was cast in a water-cooled copper mold under a high vacuum atmosphere to give an ingot. Subsequently, the surface layer of the produced ingot was removed to give a size of φ160×190 t, followed by hot-forging at 900° C. into φ200. Subsequently, cold-rolling and hot-rolling at 900° C. were performed to give a size of φ700×10 t.

Subsequently, after heat treatment at 600° C. for 1 hour, the entire target was quenched to give a target material. The target material was machined into a target having a diameter of 650 mm and a thickness of 7 mm. The target was further machined so as to have a diameter of 430 mm and a thickness of 7 mm, which was diffusion bonded to a Cu alloy backing plate into a sputtering target assembly.

### Comparative Example 4

High-purity copper (Cu) having a purity of 6 N was melted in a carbon crucible under a high vacuum atmosphere. High-purity manganese (Mn) having a purity of 5 N was charged into the molten copper. The amount of Mn was adjusted to 10 wt. %.

The molten copper-manganese alloy prepared by charging of the Mn and melting at 1500° C. for 40 minutes was cast in a water-cooled copper mold under a high vacuum atmosphere to give an ingot. Subsequently, the surface layer of the produced ingot was removed to give a size of φ160×190 t, followed by hot-forging at 900° C. into φ200. Subsequently, cold-rolling and hot-rolling at 900° C. were performed to give a size of φ700×10 t.

Subsequently, after heat treatment at 600° C. for 1 hour, the entire target was quenched to give a target material. The target material was machined into a target having a diameter of 650 mm and a thickness of 7 mm. The target was further machined so as to have a diameter of 430 mm and a thickness of 7 mm, which was diffusion bonded to a Cu alloy backing plate into a sputtering target assembly.

The high-purity copper alloy sputtering targets were each evaluated by forming a thin film with a thickness of 600 nm on a 300-mm monocrystalline silicon wafer covered with silicon oxide under sputtering conditions shown below and particles generated during the sputtering was investigated. The particles on the wafer surface were counted with a particle counter available from KLA-Tencor Corporation, and the average number in 20 wafers was determined. Table 1 shows the comparison results of the rate of particles of 0.20 μm or more and particles of 0.08 μm or more which were generated during sputtering.

(Sputtering conditions)

Apparatus: Endura manufactured by Applied Materials, Inc.

Power source: direct current system

Power: 40 kW

Ultimate vacuum: 5×10⁻⁶ Pa

Atmospheric gas composition: Ar

Sputtering gas pressure: 55 Pa

Sputtering time: 6 seconds

TABLE 1

| | | | | Number of particles | |
|---|---|---|---|---|---|
| | | | | on wafer (average) | |
| | Melting conditions | | | 0.20 μm | 0.08 μm |
| | Temper- | | Carbon | or more | or more |
| | ature | Time | amount | (Number/ | (Number/ |
| | (° C.) | (min) | (wt ppm) | Wafer) | Wafer) |
| Example 1 | 1200 | 20 | 1 | 2.2 | 9.9 |
| Example 2 | 1200 | 20 | 2 | 5.4 | 12.1 |
| Example 3 | 1200 | 20 | 1 | 2.3 | 10.2 |
| Example 4 | 1200 | 20 | 2 | 5.3 | 11.9 |
| Comparative | 1500 | 40 | 5 | 37.3 | 98.6 |
| Example 1 | | | | | |
| Comparative | 1500 | 40 | 10 | 42.7 | 129.3 |
| Example 2 | | | | | |
| Comparative | 1500 | 40 | 5 | 39.8 | 109.2 |
| Example 3 | | | | | |
| Comparative | 1500 | 40 | 10 | 52.3 | 139.2 |
| Example 4 | | | | | |

1 Wafer = 300 mm φ

As shown in Table 1, when the carbon amount was 1 wt ppm in Examples 1 and 3, the numbers of particles generated and having a diameter of 0.20 μm or more were respectively 2.2 and 2.3, and the numbers of particles having a diameter of 0.08 μm or more were respectively 9.9 and 10.2.

Whereas, when the carbon amount was 2 wt ppm in Examples 2 and 4, the numbers of particles having a diameter of 0.20 μm or more were respectively 5.4 and 5.3 and the numbers of particles having a diameter of 0.08 μm or more were respectively 12.1 and 11.9.

In contrast, when the carbon amount was 5 wt ppm in Comparative Examples 1 and 3, the numbers of particles having a diameter of 0.20 μm or more were respectively 37.3 and 39.8 and the average numbers of particles having a diameter of 0.08 μm or more were respectively 98.6 and 109.2.

Meanwhile, when the carbon amount was 10 wt ppm in Comparative Examples 2 and 4, the average numbers of particles having a diameter of 0.20 μm or more were respectively 42.7 and 52.3 and the average numbers of particles having a diameter of 0.08 μm or more and respectively 129.3 and 139.2.

Thus, there was an obvious difference in generation of particles, i.e., a carbon amount of 2 wt ppm or less gave satisfactory results of significantly reducing particles.

In addition, it was revealed that the generation of particles depends on the amount of carbon and does not depend on the size of a target.

### INDUSTRIAL APPLICABILITY

The present invention provides a copper-manganese-alloy sputtering target that effectively suppresses the particle generation during sputtering by adding an appropriate amount of Mn element to copper and controlling the amount of carbon. In particular, the target can successfully form a metal line (via) of fine semiconductor devices and thereby shows an excellent effect of improving the yield and the reliability of semiconductor products, which have been progressing in miniaturization and integration. In addition, the target is useful for forming a semiconductor copper-manganese-alloy line having a self-diffusion suppression function, capable of effectively preventing the periphery of the line from being contaminated by diffusion of active Cu, and having excellent, for example, electron migration (EM) resistance and corrosion resistance.

1. A high-purity copper-manganese-alloy sputtering target comprising 0.05 to 20 wt. % of Mn, 2 wt ppm or less of C, and the remainder being Cu and inevitable impurities, wherein in formation of a film on a wafer by sputtering the target, the number of particles composed of C, at least one element selected from Mn, Si, and Mg, or a compound composed of C and at least one element selected from Mn, Si, and Mg and having a diameter of 0.08 μm or more is 50 or less on average.

2. The high-purity copper-manganese-alloy sputtering target according to claim 1, wherein the number of particles having a diameter of 0.08 μm or more is 20 or less on average.

3. A high-purity copper-manganese-alloy sputtering target comprising 0.05 to 20 wt. % of Mn, 2 wt ppm or less of C, and the remainder being Cu and inevitable impurities, wherein in formation of a film on a wafer by sputtering the target, the number of particles composed of C, at least one element selected from Mn, Si, and Mg, or a compound composed of C and at least one element selected from Mn, Si, and Mg and having a diameter of 0.20 μm or more is 30 or less on average.

4. The high-purity copper-manganese-alloy sputtering target according to claim 3, wherein the number of particles having a diameter of 0.20 μm or more is 10 or less on average.
